(19) United States
(12) Patent Application Publication
(10) Pub. No.: US 2008/0253080 A1
(43) Pub. Date: Oct. 16, 2008

(54) PANEL-TYPE HEAT SINK MODULE

(75) Inventors: Sin-Wei HE, Jhudong Township (TW); Jhong-Yan Chang, Hsinchu City (TW)

Correspondence Address: EGBERT LAW OFFICES, 412 MAIN STREET, 7TH FLOOR, HOUSTON, TX, 77002, US

(73) Assignee: FORCECON TECHNOLOGY Co., Ltd., Chu Pei City (TW)

(21) Appl. No.: 11/744,421

(22) Filed: May 4, 2007

(30) Foreign Application Priority Data
Sep. 22, 2006 (TW) 095217028

(51) Int. Cl. H05K 7/20

(52) U.S. Cl. 361/687

(57) ABSTRACT

The panel-type heat sink module combines the heat-conducting panel, fin heat sink, diversion tank, fan and heat pipe into a single module. There is a heat-conducting surface and an assembly surface of the heat-conducting panel. The fin heat sink is assembled onto the assembly surface. The diversion tank is adapted onto the assembly surface and located nearby the fin heat sink. The diversion tank includes a fan container and a diversion channel. The fan is assembled into the fan container, and the heat pipe is assembled between the assembly surface and the fin heat sink. The heat pipe penetrates through the diversion tank; thus, the heat sources guided by the heat-conducting panel will be uniformly guided into the fin heat sink and diversion tank via the heat pipe. An air stream generated by the fan flows towards the fin heat sink, improving heat-radiation, and reducing assembly space.

### CROSS-REFERENCE TO RELATED U.S. APPLICATIONS

Not applicable.

### STATEMENT REGARDING FEDERALLY SPONSORED RESEARCH OR DEVELOPMENT

Not applicable.

### NAMES OF PARTIES TO A JOINT RESEARCH AGREEMENT

Not applicable.

### REFERENCE TO AN APPENDIX SUBMITTED ON COMPACT DISC

Not applicable.

### BACKGROUND OF THE INVENTION

1. Field of the Invention

The present invention relates generally to a heat sink module, and more particularly to an innovative module combining a heat-conducting panel, a fin heat sink, a diversion tank, fan and a heat pipe.

2. Description of Related Art Including Information Disclosed Under 37 CFR 1.97 and 37 CFR 1.98.

With the improvement of performance in currently available displays (e.g. LED and LCD) and panel-type LED lights accompanied by increased energy generation, a challenging task for the panel display industry is how to improve heat-sinking capability, while maintaining normal operation and service life of electronic components.

Notwithstanding the existing solutions for the heat-sinking problems, typical displays and panel-type LED lights enable heat radiation only by fin heat sinks, by fans, or by heat tubes. Because of discrete components and imperfect configuration, no optimum heat-sinking effect can be achieved. Furthermore, the problems of inconvenient assembly and greater space demands still require consideration in the effort to optimize heat-sinking effects.

Thus, to overcome the aforementioned problems of the prior art, it would be an advancement in the art to provide an improved structure that can significantly improve efficacy.

To this end, the inventor has provided the present invention of practicability after deliberate design and evaluation based on years of experience in the production, development and design of related products.

### BRIEF SUMMARY OF THE INVENTION

There is enhanced efficacy of the present invention. The panel-type heat sink module of the present invention includes a heat-conducting panel 10, fin heat sink 20, diversion tank 30, fan 40, and heat pipe 50. These parts are combined into a single module.

The module of the present invention has the following functions:

1. Significant improvement of heat-radiation efficiency. The heat-conducting panel 10 extensively absorbs and inducts heat sources. Then, the heat is uniformly guided into the fin heat sink 20 and diversion tank 30 via heat pipe 50. Next, the running fan 40 generates cold air W flowing towards fin heat sink 20. Thus, a complete heat-sink structure can be formed, thus making it possible to significantly improve heat radiation efficiency.

2. More convenient assembly. Since the heat-conducting panel 10, fin heat sink 20, diversion tank 30, fan 40, and heat pipe 50 are combined into a single module, the assembly of existing LCD display panels, LED lighting panels or LED display panels is able to be performed more efficiently, thus greatly shortening the assembly time with lower cost.

3. Reduction of assembly space. Since the heat-conducting panel 10, fin heat sink 20, diversion tank 30, fan 40, and heat pipe 50 are combined into a single module, the entire heat sink module A can be developed into a compact and thin-profile structure, thus contributing to reduce the assembly space for the development of lightweight electronic products.

Although the invention has been explained in relation to its preferred embodiment, it is to be understood that many other possible modifications and variations can be made without departing from the spirit and scope of the invention as hereinafter claimed.

### BRIEF DESCRIPTION OF THE SEVERAL VIEWS OF THE DRAWINGS

FIG. 1 shows an assembled perspective view of the heat sink module of the present invention.

FIG. 2 shows an exploded perspective view of the heat sink module of the present invention, viewed from another angle.

FIG. 3 shows an assembled perspective view of the heat sink module of the present invention, viewed from still another angle.

FIG. 4 shows a perspective view of a portion of the heat sink module of the present invention.

FIG. 5 shows a sectional view of the heat sink module of the present invention.

FIG. 6 shows a top plan view of the heat sink module of the present invention.

FIG. 7 shows a top plan view of the internal structure of the heat sink module and the fan in running state.

FIG. 8 shows another perspective view of the application of the heat pipe in the heat sink module of the present invention.

### DETAILED DESCRIPTION OF THE INVENTION

The features and the advantages of the present invention will be more readily understood upon a thoughtful deliberation of the following detailed description of a preferred embodiment of the present invention with reference to the accompanying drawings.

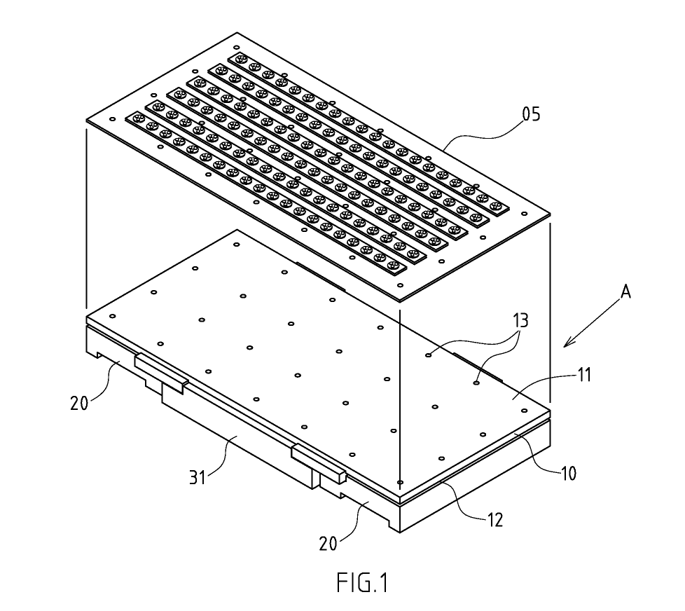

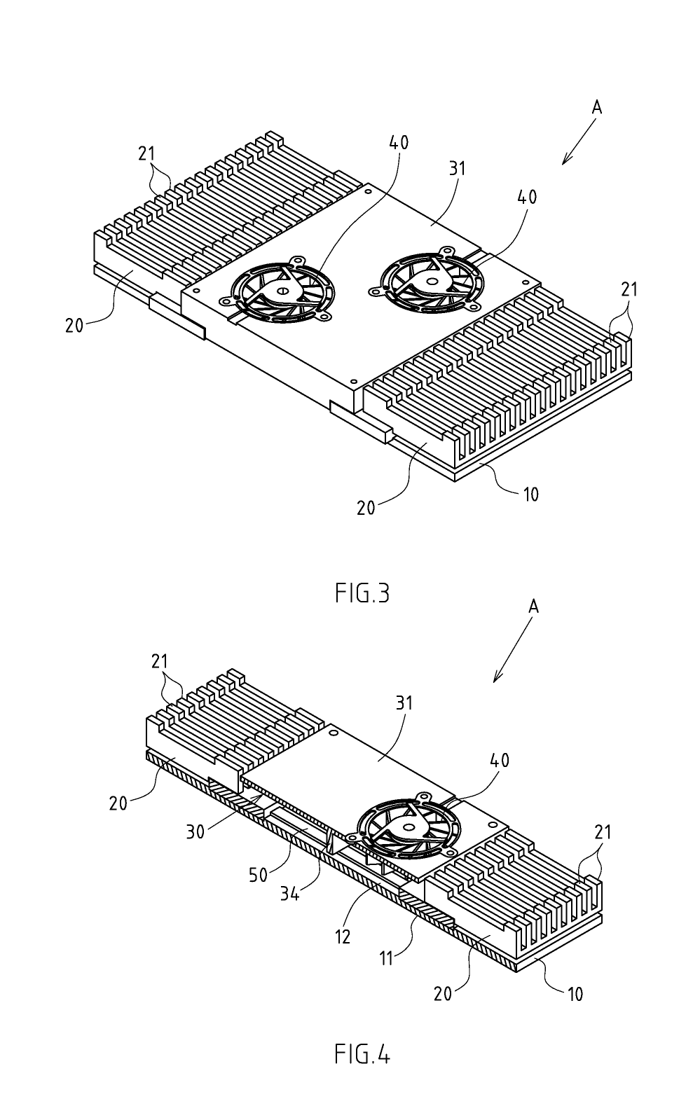

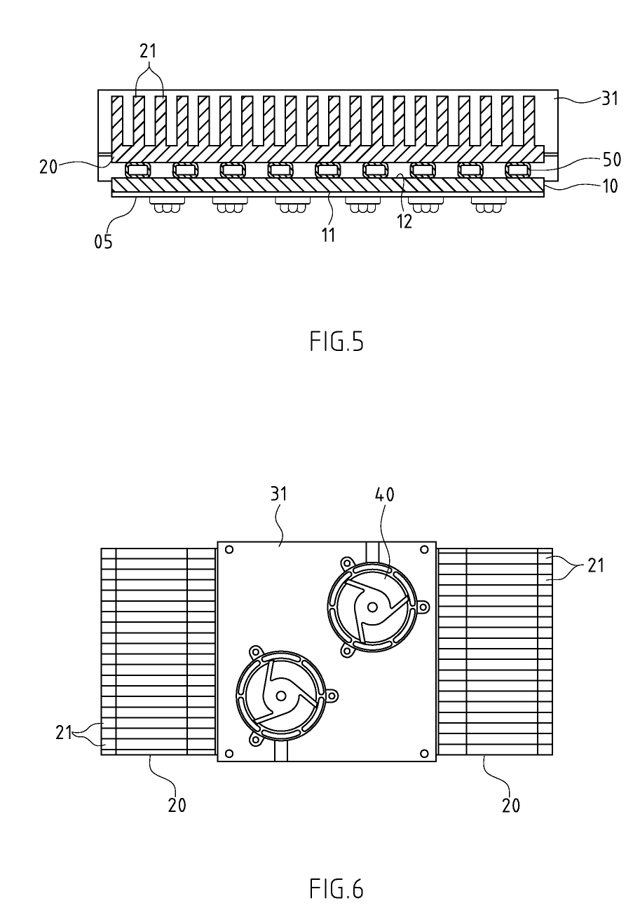

FIGS. 1, 2, 3, 4, 5, and 6 depict preferred embodiments of an improved panel-type heat sink module of the present invention. The embodiments are provided only for explanatory objectives.

The heat sink module A of the present invention includes a heat-conducting panel 10 with preset dimension and thickness. The panel 10 has a defined a heat-conducting surface 11 and an assembly surface 12. Some mounting holes 13 are arranged at intervals on the heat-conducting surface 11 of the heat-conducting panel 10, thus helping to position the existing LCD display panel 05, lighting panel, or LCD panel. The specific example of the LCD panel is shown in FIG. 1.

At least a fin heat sink 20 is assembled into a preset location on the assembly surface 12 of the heat-conducting panel 10. The fin heat sink 20 comprises several fins 21 arranged at intervals.

A diversion tank 30 is adapted onto the assembly surface 12 of the heat-conducting panel 10, and is formed by an enclosed space of a housing 31. The diversion tank 30 is also located nearby the fin heat sink 20. The diversion tank 30 is comprised of a fan container 32 and a diversion channel 33. The diversion channel 33 is used to connect the fan container 32 and fin heat sink 20.

At least a fan 40 is assembled into the fan container 32 of the diversion tank 30, and used to guide external air into the diversion tank 30. An generate air stream flowing towards the fin heat sink 20 is then generated by the fan 40.

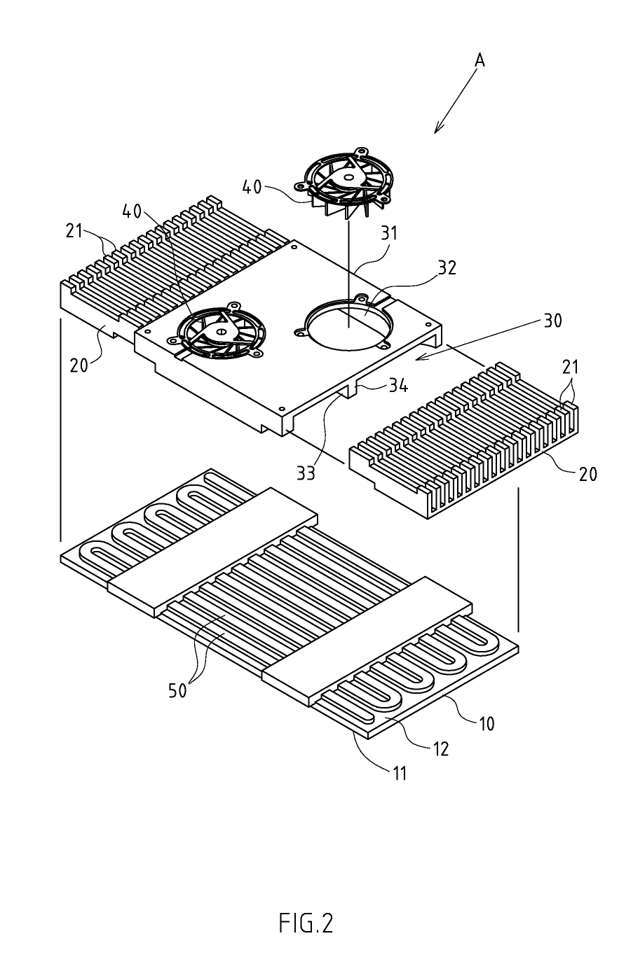

At least a heat pipe 50 is assembled between the assembly surface 12 of the heat-conducting panel 10 and the fin heat sink 20. One end or one section of the heat pipe 50 penetrates through the diversion tank 30. The heat pipe 50 may be composed of manifold pipes as shown in FIG. 2, or the heat pipe 50B may be composed of several pipes arranged at intervals, as shown in FIG. 8.

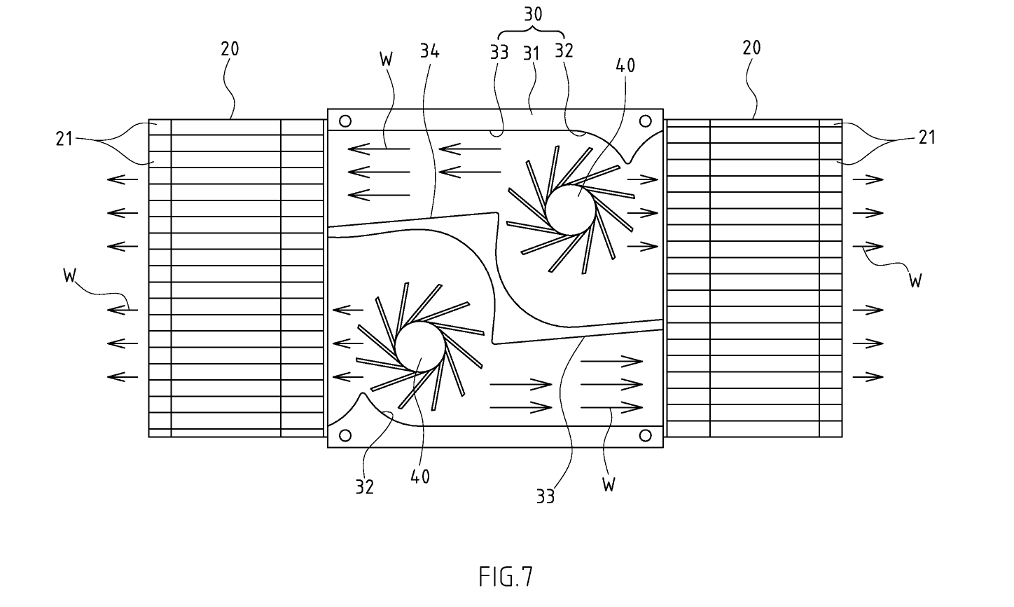

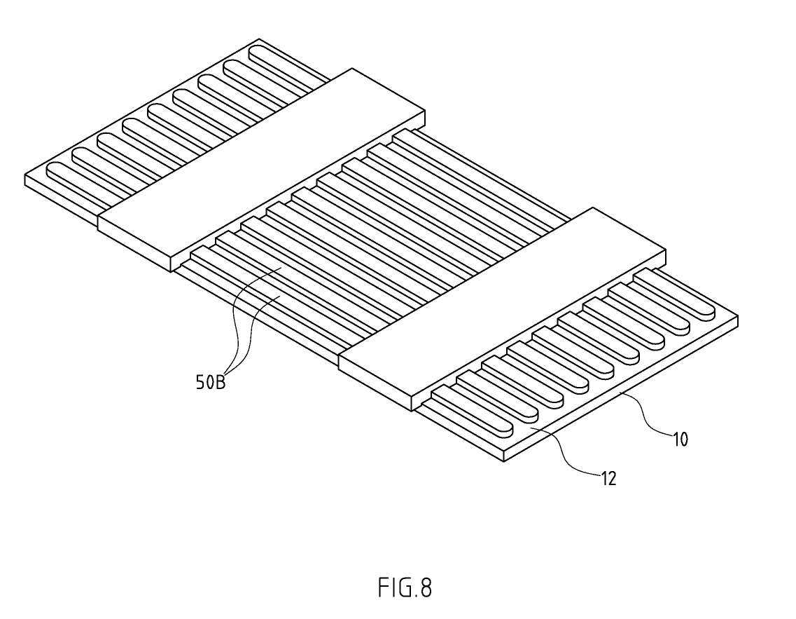

The fin heat sinks 20 of the preferred embodiment are divided into two parts and separately assembled at both sides of the assembly surface 12 of the heat-conducting panel 10. Thus, the diversion tank 30 is placed between two fin heat sinks 20. Two fans 40 are misaligned and separated by a wall 34 as shown in FIG. 7. Independent space for the diversion channels 33 is formed. Moreover, two diversion channels 33 are separately connected to the fin heat sink 20.

Based upon above-specified structures, the present invention is operated as follows:

FIG. 1 depicts the preferred embodiment of the heat sink module A of the present invention, wherein some mounting holes 13 are arranged on the heat-conducting surface 11 of the heat-conducting panel 10, thus helping to position the existing LCD display panel 05 (or LED lighting panel or LED display panel).

When the heat sink module of the present invention is activated, the heat-conducting panel 10 extensively absorbs and inducts heat sources generated by the LCD display panel 05 (or LED lighting panel or LED display panel). Then, the heat of the heat sources will be uniformly guided into the fin heat sink 20 and diversion tank 30 via heat pipe 50. Next, the running fan 40 will generate cold air W flowing towards fin heat sink 20 as shown in FIG. 7. The cold air W flows through the gap between the fins 21 of the fin heat sink 20, so that the heat absorbed by the fin heat sink 20 rapidly dissipates. On the other hand, the heat generated from the heat pipe 50 passing through the diversion tank 30 can also be dissipated rapidly by the fan 40, thus achieving a desirable cooling or heat radiation effect.

1. A panel-type heat sink module, comprising:
a heat-conducting panel with preset dimensions and thickness, said heat-conducting panel having a heat-conducting surface and an assembly surface;
a fin heat sink, being assembled in a preset location on said assembly surface, said fin heat sink being comprised of a plurality of fins arranged at intervals;
a diversion tank, being adapted onto said assembly surface and located nearby said fin heat sink, said diversion tank being comprised of a fan container and a diversion channel, said diversion channel connecting said fan container and said fin heat sink;
a fan, being assembled in said fan container and used to guide external air into said diversion tank, an air stream flowing towards said fin heat sink being generated by said fan; and
a heat pipe, being assembled between said assembly surface and said fin heat sink, said heat pipe having one end or one section thereof penetrating through the said diversion tank.

2. The module defined in claim 1, wherein said fin heat sink divides into two parts, said two parts being separately assembled at both sides of said assembly surface, said diversion tank being placed between said two parts of said fin heat sink.

3. The module defined in claim 1, wherein said fan is comprised of two misaligned fans separated by a wall, forming independent space for said diversion channels, said diversion channel being separately connected to said fin heat sink.

4. The module defined in claim 1, wherein said heat-conducting surface has a plurality of mounting holes arranged at interval thereon.

5. The module defined in claim 4, wherein said mounting holes position an LED display panel or lighting panel or LCD panel.
